(19) United States
(12) Patent Application Publication
(10) Pub. No.: US 2006/0140009 A1
(43) Pub. Date: Jun. 29, 2006

(54) Programming method for nanocrystal memory device

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/021,658

(22) Filed: Dec. 23, 2004

(51) Int. Cl. G11C 16/04

(52) U.S. Cl. 365/185.28

(57) ABSTRACT

A programming method for non-volatile electrically erasable and programmable CMOS memory transistor lowers programming power requirements. First, a nanocrystal floating gate is provided in electrical communication to source and drain electrodes of the transistor. Secondly, bipolar programming pulses are applied to the substrate, with a control gate held at a steady voltage. A first polarity partial cycle of the programming pulse creates space charge in the channel region between source and drain electrodes. A second polarity partial cycle drives at least a portion of the space charge onto the floating gate thereby establishing a charged state for the transistor corresponding to a binary digit. The non-charged state represents another binary digit.

### TECHNICAL FIELD

The invention relates generally to CMOS non-volatile nanocrystal memory transistors and in particular to a programming method for such a transistor.

### BACKGROUND ART

Non-volatile memory transistors that are electrically programmable and erasable, i.e. EEPROMs, or flash memory transistors, feature a floating gate where charge is stored to indicate a memory state. Most frequently, the gate is made of polysilicon and has an overlying control gate where different voltages are applied for writing and erasing. Writing may be accomplished by pulling or accelerating electrons from a supply onto the floating gate, while erasing is typically, but not necessarily, a reverse process. While application of appropriate voltages to EEPROM electrodes will program the transistors, some enhanced programming techniques exist. In U.S. Pat. No. 6,507,521 a pulse programming technique is disclosed.

In recent years, floating gates have been formed from nanocrystal structures. See, for example, U.S. Pat. No. 6,690,059 to B. Lojek or the article entitled “A Silicon Nanocrystals Based Memory” by S. Tiwari et al. in Appl. Phys. Lett. 68(10), p. 1377-1379, 4 Mar. 1996. In programming nanocrystal transistors, charge must be transferred to the nanocrystals from a supply, usually a source or drain electrode, or both. Various charge transfer techniques have been used including Fowler-Nordheim tunneling, hot electron transfer, impact ionization, and so on.

For the most part, programming involves application of an appropriate potential difference between two electrodes, typically the control gate and source or drain.

In an EEPROM 10 of the prior art, shown in FIGS. 1 and 2, a conductive floating gate 11, typically made of polysilicon, is located over and between source and drain electrodes 13 and 15 of a first conductivity type, here shown as n+, separated therefrom by thin oxide in region 12. Electrical conductivity between source 13 and drain 15 is through channel 18, existing in the substrate of a second conductivity type, here a p-well. Floating gate 11 controls such conductivity in a manner such that charge stored on the floating gate can shut off conduction, thereby performing a switch function. Control gate 17, spaced apart from floating gate 11 by an oxide layer, is used to pull or accelerate charge from the source and drain onto the floating gate, as shown in FIG. 2 or to remove charge, not shown.

In the pulse programming technique described in the '521 patent, shown in FIGS. 1 and 2, a bipolar pulse voltage is applied to p-well 21 of a floating gate transistor with a level of approximately 1 V at terminal 22 on the high level side, seen in FIG. 1, and a level of −5 to −7 V at terminal 22 on the low level side, as seen in FIG. 2. When 1 V is applied to a p-well 21, as seen in FIG. 1 at terminal 22, the resulting forward bias causes electrons 20 to be injected from source 13 and drain 15 into the channel 18, a part of the p-well 21. As the pulse voltage applied to the p-type well changes to −5 V, seen in FIG. 2 at terminal 22, a depletion layer 23 is formed in the channel region. At the depletion layer, the electrons 20 are accelerated toward a tunnel oxide film 12. The electrons having been accelerated in the channel are injected into the tunnel oxide film and are trapped at floating gate 11. In FIG. 3, the positive and negative going pulse segment 31 is followed by the negative going segment 33, both part of a pulse train 35 that operates at a nominal frequency of 1 MHz according to the '521 patent.

While this programming method is an improvement in low power programming, it is desirable to reduce programming power even further.

### SUMMARY OF THE INVENTION

We have discovered that pulse programming may be applied to floating gate non-volatile transistor memory cells wherein a floating gate having electrically conductive nanocrystals embedded in a dielectric matrix is placed in proximity to the substrate. The transistor substrate is of a second conductivity type while source and drain regions are of a first conductivity type. The source and drain should be in electric field communication with the nanocrystals. An electrically conductive control gate is disposed over the dielectric material of the nanocrystal layer. To program the nanocrystals, a bipolar voltage pulse is applied to the substrate while the control gate is held as a positive voltage. The bipolar pulses are applied as in a manner similar to the prior art described above, but have a voltage range less than in the prior art. We have found that a positive going pulse in the range of 0.5 to 1.5 volts and a negative going value in the range of −3.5 volts to −4.5 volts is ideal for programming the nanocrystals. A power reduction of at least twenty percent over the prior art may be gained by applying pulse programming to nano-crystal floating gate devices, together with a reduction in transistor cell size.

### BRIEF DESCRIPTION OF THE DRAWINGS

FIGS. 1 and 2 show a non-volatile memory cell of the prior art with programming of the floating gate by a positive going pulse applied to the substrate in FIG. 1 and a negative going pulse applied to the substrate in FIG. 2.

FIG. 3 is a voltage versus time plot for programming pulses applied to the substrate in FIGS. 1 and 2.

FIG. 4 is a side sectional view of a non-volatile memory transistor having a floating gate formed of nanocrystals.

FIGS. 5 and 6 illustrate a nanocrystal memory device as in FIG. 4, with positive and negative pulse segments applied to the substrate.

FIG. 7 is a voltage versus time plot for programming pulses applied to the substrate in FIGS. 5 and 6.

FIG. 8 illustrates a pulse train of pulses of the type shown in FIG. 7.

FIG. 9 is an alternative method of supplying charge to the floating gate of a non-volatile transistor memory of the type illustrated in FIG. 4.

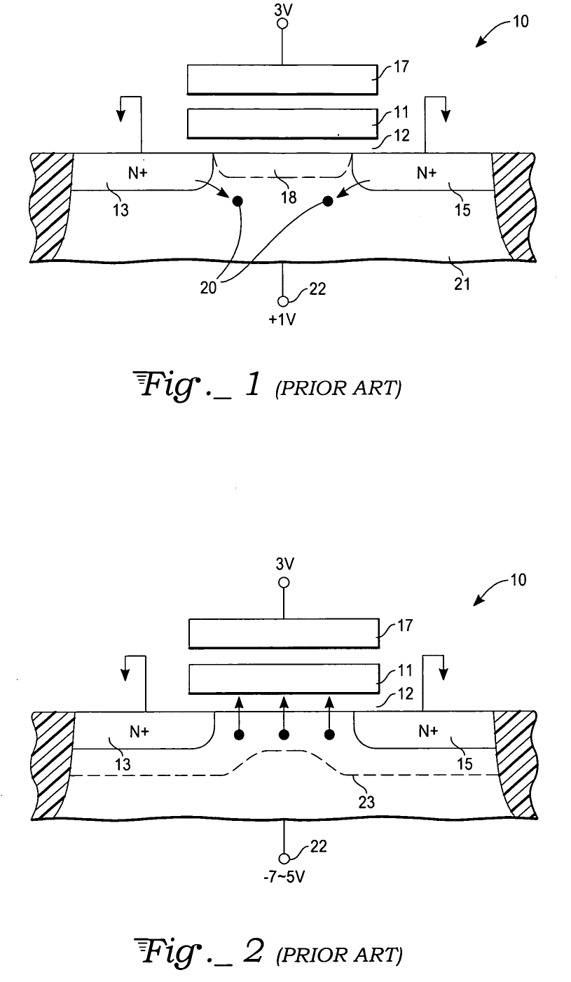

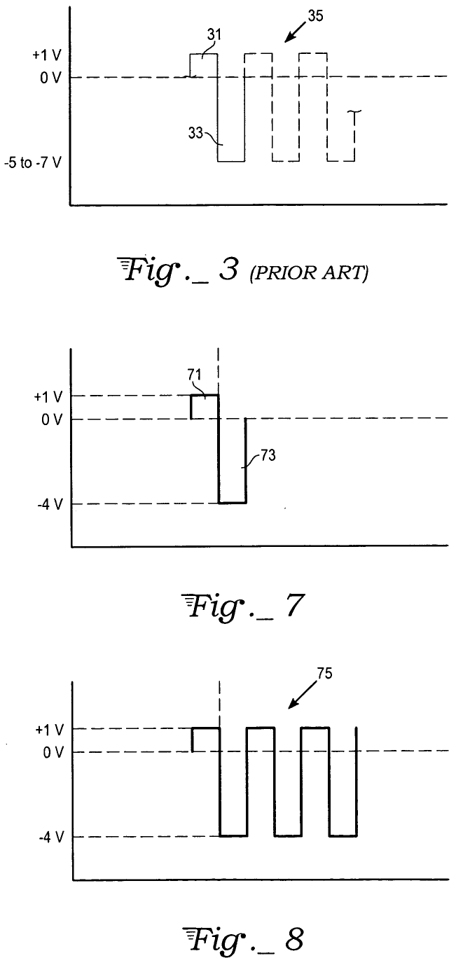

### BEST MODE OF CARRYING OUT THE INVENTION

With reference to FIG. 4, a non-volatile transistor 40 is designed to have a floating gate construction. A P-well 51 is of a second conductivity type, built partly between isolation regions 52 and 54 within an N-well 53 which, in turn, is located in a P substrate 55. Ion implantation of regions 43 and 45 are of an opposite conductivity type, i.e. a first conductivity type, to the P well 51. The implantations form source 43 and drain 45 and have N+ conductivity (first conductivity type) in relation to P-well 51 (second conductivity type). The P well 51 is biased by a contact 67 to which a bipolar voltage programming pulse could be applied, as described below. Source 43 and drain 45 are maintained at ground potential by electrical leads 63 and 65. Conductivity types could be reversed as an equivalent structure.

Construction of nanocrystal floating gates is known, as previously described with reference to the '059 patent to B. Lojek. The nanocrystal floating gate 41 is disposed directly over the P well 51 of the substrate. A channel 46 will form between source and drain 43 and 45 and be controlled by charge on the floating gate 41. A conductive polysilicon control gate 47 is disposed over the floating gate 41. The control gate will have a voltage bias lead 61 having the function of providing a reference voltage.

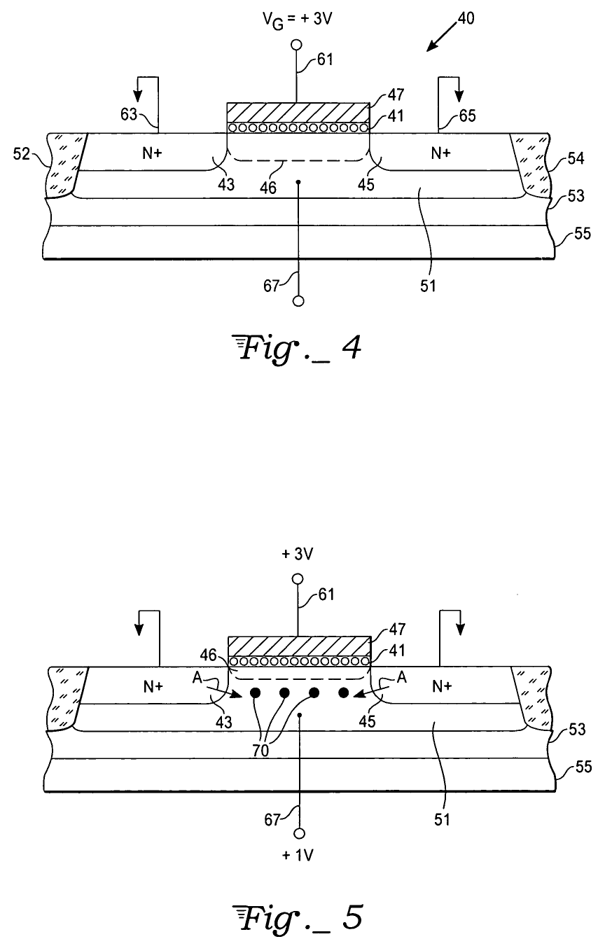

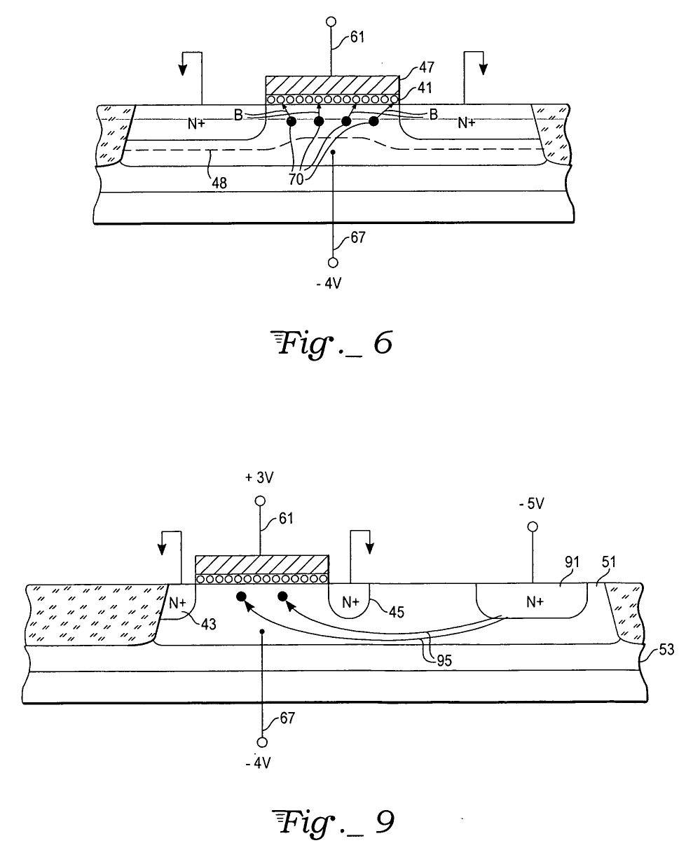

In FIG. 5, a positive going pulse segment is applied to lead 67. This voltage may be in the range of +0.5 to +1.5 volts. In FIG. 5, the voltage is seen to be +1 volt on lead 67. At the same time, +3 volts is applied to control gate 47 on lead 61, while the source and drain 43 and 45 are kept at ground potential. This voltage scheme drives electrons 70 from the source and drain, as indicated by the arrows A into the channel region between source and drain electrodes 43 and 45. This positive going pulse segment is segment 71 in FIG. 7. Returning to FIG. 5, the channel region is indicated by the dashed lines 46. The electrons form a space charge in the channel region which increases with time until a saturation level is reached. As the space charge increases toward a saturation level, an opposite voltage level is applied to lead 67. This opposite voltage has the effect of establishing a depletion layer 48, seen in FIG. 6, whereupon electrons 70 are driven out of the substrate and onto the nanocrystals within the floating gate 41 with the assistance of the positive bias on lead 61 and as indicated by arrows B. The negative voltage applied to lead 67 is in the range from −3.5 volts to −4 volts and is seen as the negative going pulse segment 73 in FIG. 7. At all times in both FIGS. 5 and 6 the control gate voltage on lead 61 is maintained at +3 volts, a value that can vary by ±0.5 volts.

In FIG. 8, a pulse train 75 is shown. The pulses illustrated in FIG. 7 are replicated in a pulse train varying between +1 volt and −4 volts. The pulse frequency is in the order of 1 MHz. Note that the voltage swing is less than in the prior art. Moreover, use of nanocrystals, rather than a solid conductive floating gate results in much less power that determines a transistor state.

With reference to FIG. 9, for certain types of nanocrystal layer construction, a greater amount of current may be needed to charge the floating gate. In this situation, an auxiliary electrode 71 of the same conductivity type as the source and drain is added to the P well 51. This electrode has a bias slightly greater, i.e. slightly more negative, than the negative pulse segment applied to lead 67. This allows the auxiliary electrode to provide additional charge to the space charge region between the source and drain 43 and 45 with charge particle paths indicated by lines 75.

In operation, the positive swing of the pulse train illustrated in FIG. 8 creates space charge in the channel region. The negative going pulse of pulse train 75 creates an electron depletion zone, tending to accelerate electrons onto the floating gate.

For both embodiments, lower power is required to program non-volatile memory transistors. The transistors become very compact structures and are ideally used in large memory arrays. In common with prior devices, a charged floating gate represents one digital state (one or zero) while an uncharged floating gate represents the opposite digital state. Sensing of charge on the floating gate is accomplished as in the prior art.

1. In a floating gate non-volatile transistor memory of the type having a p-well substrate spaced apart from n-plus source and drain electrodes in the substrate, the programming method comprising:
providing a floating gate in proximity to the substrate wherein electrically conductive nanocrystals are embedded in dielectric material, the nanocrystals being in electric field communication with at least one of the source and drain electrodes, and a conductive control gate is disposed over the dielectric material, and
applying a bipolar voltage pulse to the substrate while the control gate is held at a positive voltage, the bipolar pulses have a positive value in the range of 0.5 to 1.5 volts and a negative value in the range of −3.5 volts to −4.5 volts.

2. The method of claim 1 wherein the positive control gate voltage is in the range of 2.5 to 3.5 volts.

3. The method of claim 1 wherein the bipolar voltage pulse is a member of a pulse train of identical pulses.

4. The method of claim 1 wherein the source and drain are electrically grounded.

5. The method of claim 1 wherein the control gate is in contact with the floating gate.

6. The method of claim 1 wherein the control gate is spaced apart from the floating gate.

7. The method of claim 1 further defined by providing an auxiliary electrode of the same conductivity type as source and drain electrodes biased to provide charge to the nanocrystals in response to the bipolar voltage pulses.

8. A programming method for a nanocrystal memory CMOS transistor device of the type having source, drain and a channel therebetween, with a nanocrystal floating gate and a control gate, the method comprising:
establishing a space charge region in the channel region of the device on a first partial cycle of a bipolar programming pulse involving positive and negative voltage polarities on sequential partial cycles applied at locations on opposite sides of the channel, and
accelerating charge from the space charge region to the nanocrystal floating gate on a second partial cycle of the bipolar programming pulse applied at the same locations.

9. The method of claim 8 wherein the first partial cycle of the bipolar programming pulse has a level in the range of 0.5 to 1.5 volts of a first voltage polarity.

10. The method of claim 8 wherein the second partial cycle of the bipolar programming pulse has a level in the range of 3.5 to 4.5 volts of a second voltage polarity.

11. The method of claim 8 wherein the bipolar voltage pulse is a member of a pulse train of identical pulses.

12. The method of claim 8 wherein the source and drain are electrically grounded.

13. The method of claim 8 wherein the control gate is in contact with the floating gate.

14. The method of claim 8 wherein a control gate voltage is applied in the range of 2.5 to 3.5 volts.

15. The method of claim 8 further defined by providing an auxiliary electrode of the same conductivity type as source and drain electrodes biased to provide charge to the nanocrystals in response to the bipolar voltage pulses.

16. The method of claim 8 wherein said charge comprises electrons.

17. A programming method for a nanocrystal memory CMOS transistor device of the type having source, drain and a channel therebetween, with a nanocrystal floating gate and a control gate, the method comprising:
providing an auxiliary electrode near source and drain electrodes to at least partially create a space charge region in the channel region of the device on a first partial cycle of a bipolar programming pulse involving positive and negative voltage polarities on sequential partial cycles applied at locations on opposite sides of the channel, and
accelerating charge from the space charge region to the nanocrystal floating gate on a second partial cycle of the bipolar programming pulse applied at the same locations.

18. The method of claim 17 further defined by providing a continuous bias on said auxiliary electrode.

19. The method of claim 18 wherein said continuous bias exceeds the level of the bipolar programming pulse.

20. The method of claim 18 wherein said first and second partial cycles are half cycles.
